(19) United States
(12) Patent Application Publication
(10) Pub. No.: US 2024/0063032 A1
(43) Pub. Date: Feb. 22, 2024

(54) APPARATUS AND METHOD FOR MANUFACTURING DISPLAY APPARATUS

(71) Applicant: Samsung Display Co., Ltd., Yongin-si (KR)

(72) Inventor: Sehun Choi, Yongin-si (KR)

(73) Assignee: Samsung Display Co., Ltd., Yongin-si (KR)

(21) Appl. No.: 18/304,473

(22) Filed: Apr. 21, 2023

(30) Foreign Application Priority Data
Aug. 18, 2022 (KR) 10-2022-0103341

(51) Int. Cl. H01L 21/67; H10K 59/12; H10K 71/00; H01L 21/677

(52) U.S. Cl. CPC H01L 21/67092; H10K 59/1201; H10K 71/851; H01L 21/677; H01L 21/68707

(57) ABSTRACT

According to an embodiment, an apparatus for manufacturing a display apparatus includes a separation part to separate a half-cut target into a plurality of target portions, wherein the separation part includes a plurality of first moving parts each driven in a driving direction to move the target, and as each of the plurality of first moving parts is driven, a distance between the separated target portions gradually increases.

### CROSS-REFERENCE TO RELATED APPLICATION(S)

This application claims priority to and benefits of Korean Patent Application No. 10-2022-0103341 under 35 U.S.C. § 119, filed on Aug. 18, 2022, in the Korean Intellectual Property Office, the entire contents of which are incorporated herein by reference herein.

### BACKGROUND

### 1. Technical Field

One or more embodiments relate to an apparatus and method for manufacturing a display apparatus.

### 2. Description of the Related Art

Recently, electronic devices have been widely used. Electronic devices have been variously used as mobile electronic devices and fixed electronic devices. Such electronic devices include display apparatuses that may provide a user with visual information such as images or videos to support various functions.

A display apparatus visually displays data and is formed by depositing various layers such as an organic layer, a metal layer, and the like. To form a plurality of layers of a display apparatus, a deposition material may be deposited. For example, as a deposition material is sprayed from a deposition source, the deposition material is deposited on a substrate through a mask assembly. In case that interference occurs between a mask sheet and a shield stick, the deposition material may not be deposited at a required position on the substrate, thereby degrading deposition quality.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments include a method of separating a half-cut target by using a simple structure.

However, the embodiments are not limited thereto.

Additional aspects will be set forth in part in the description which follows and, in part, will be apparent from the description, or may be learned by practice of the embodiments.

According to one or more embodiments, an apparatus for manufacturing a display apparatus may include a separation part that separates a half-cut target into a plurality of target portions, wherein the separation part may include a plurality of first moving parts each driven in a driving direction to move the plurality of target portions, and as each of the plurality of first moving parts is driven, a distance between the plurality of target portions separated gradually increases.

At least one of the plurality of first moving parts may include a conveyor forming an endless track.

The apparatus may further include a second moving part that moves at least one of the plurality of first moving parts in a direction intersecting the driving direction.

The second moving part may move at least one of the plurality of first moving parts in a direction perpendicular to the driving direction.

Driving directions of at least two of the plurality of first moving parts may intersect each other.

The apparatus may further include a transfer robot that transfers the plurality of target portions to a storage location.

The transfer robot may include a first transfer robot, and a second transfer robot, wherein the first transfer robot and the second transfer robot may sequentially transfer the plurality of target portions to the storage location.

The transfer robot may include an adsorbing part that adsorbs the plurality of target portions.

The apparatus may further include a residue storage storing residue of the plurality of target portions separated by the separation part.

The residue storage may crush the stored residue of the plurality of target portions.

According to one or more embodiments, a method of manufacturing a display apparatus may include half-cutting a target, and separating the half-cut target into a plurality of target portions, wherein the separating may include driving a 1-1^{th} moving part in a 1-1^{th} direction to move at least one of the target portions, and driving a 1-2^{th} moving part in a 1-2^{th} direction to move at least one of the target portions, and in case that each of the 1-1^{th} moving part and the 1-2^{th} moving part is driven, a distance between the plurality of target portions separated gradually increases.

At least one of the 1-1^{th} moving part and the 1-2^{th} moving part may include a conveyor forming an endless track.

The separating may further include driving a 2-1^{th} moving part to move the 1-2^{th} moving part in a 2-1^{th} direction intersecting the 1-1^{th} direction.

The driving of the 2-1^{th} moving part to move the 1-2^{th} moving part in the 2-1^{th} direction may include driving the 2-1^{th} moving part to move the 1-2^{th} moving part in the 2-1^{th} direction perpendicular to the 1-1^{th} direction.

The 1-1^{th} direction and the 1-2^{th} direction may intersect each other.

The method may further include transferring the plurality of target portions to a storage location by using a transfer robot.

The transferring of the plurality of target portions may include sequentially transferring the plurality of target portions to the storage location by using a first transfer robot and a second transfer robot.

The transfer robot may include an adsorbing part that adsorbs the plurality of target portions.

The method may further include storing residue of the plurality of target portions separated in a residue storage.

The residue storage may crush the stored residue of the plurality of target portions.

Other aspects, features, and advantages of the disclosure will become more apparent from the drawings, the claims, and the detailed description.

It is to be understood that the embodiments above are described in a generic and explanatory sense only and not for the purpose of limitation, and the disclosure is not limited to the embodiments described above.

### BRIEF DESCRIPTION OF THE DRAWINGS

The above and other aspects, features, and advantages of certain embodiments will be more apparent from the following description taken in conjunction with the accompanying drawings, in which:

FIG. 1 is a schematic perspective view illustrating an apparatus for manufacturing a display apparatus, according to an embodiment;

FIGS. 2A to 2C are schematic views for describing a chucking unit, according to an embodiment;

FIGS. 3A and 3B are schematic views for describing a cutting unit, according to an embodiment;

FIG. 4 is a schematic view for describing a transfer unit, according to an embodiment;

FIGS. 5A and 5B are schematic views for describing a separation unit, according to an embodiment;

FIG. 6 is a schematic view for describing a transfer robot, according to an embodiment;

FIGS. 7A and 7B are schematic views for describing a residue storage unit, according to an embodiment;

FIGS. 8A and 8B are schematic views for describing a separation unit, according to another embodiment;

FIG. 9 is a schematic plan view illustrating a display apparatus, according to an embodiment; and

FIG. 10 is a schematic cross-sectional view illustrating a display apparatus, according to an embodiment.

FIG. 11 is a schematic diagram of an equivalent circuit illustrating a pixel, according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

It will be understood that the terms “connected to” or “coupled to” may refer to a physical, electrical and/or fluid connection or coupling, with or without intervening elements.

As used herein, the expressions used in the singular such as “a,” “an,” and “the,” are intended to include the plural forms as well, unless the context clearly indicates otherwise.

As used herein, the term “and/of” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In case that a certain embodiment may be implemented differently, a specific process order may be different from the described order. For example, two consecutively described processes may be performed substantially at the same time or may be performed in an order opposite to the described order.

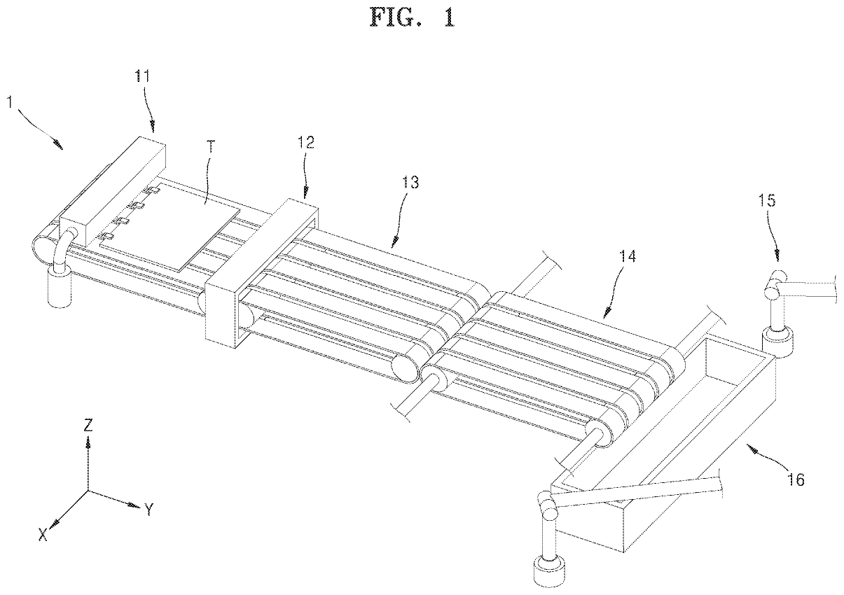

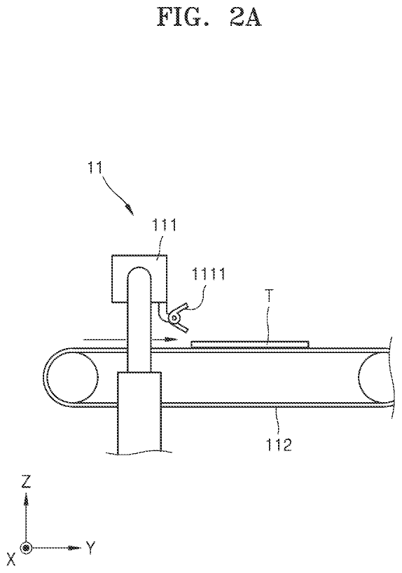

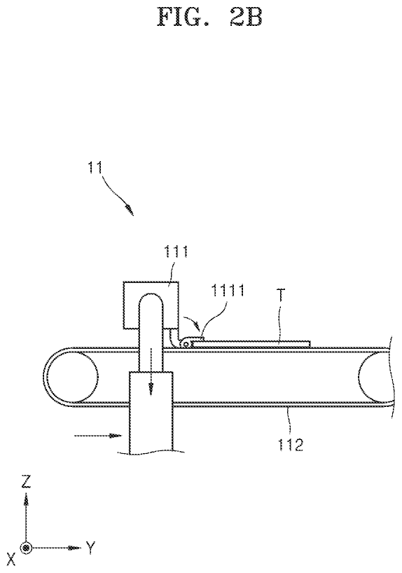

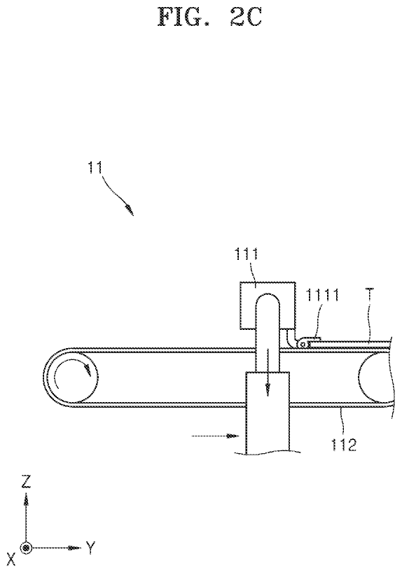

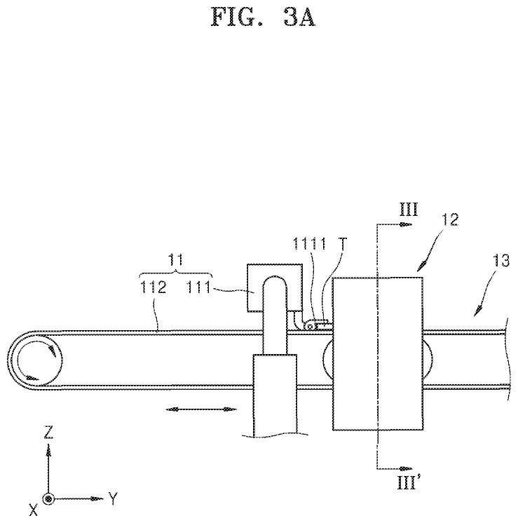

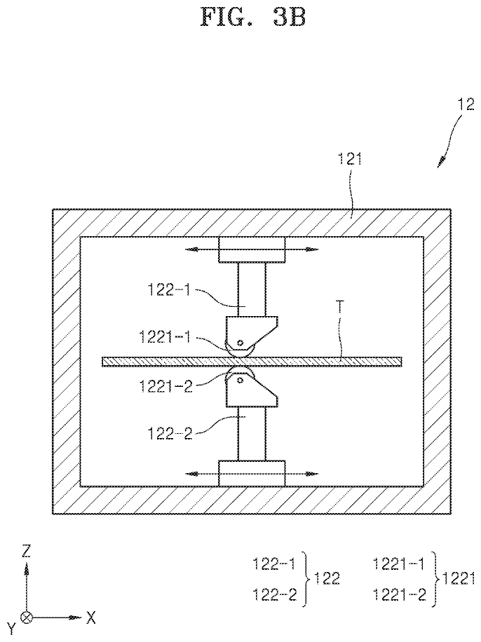

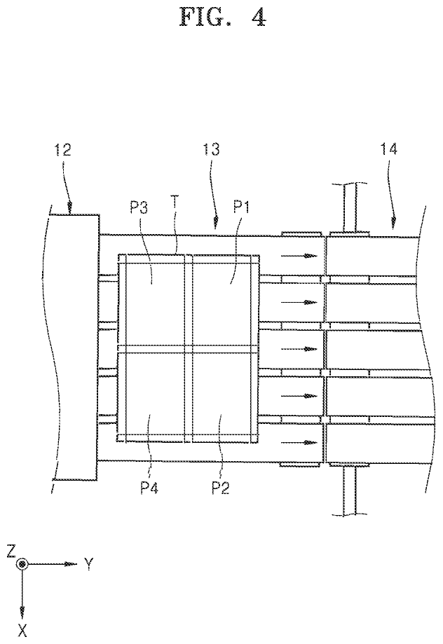

FIG. 1 is a schematic perspective view illustrating an apparatus for manufacturing a display apparatus, according to an embodiment. FIGS. 2A to 2C are schematic views for describing a chucking unit (chucking part), according to an embodiment. FIGS. 3A and 3B are schematic views for describing a cutting unit (cutting part), according to an embodiment. FIG. 4 is a schematic view for describing a transfer unit (transfer part), according to an embodiment.

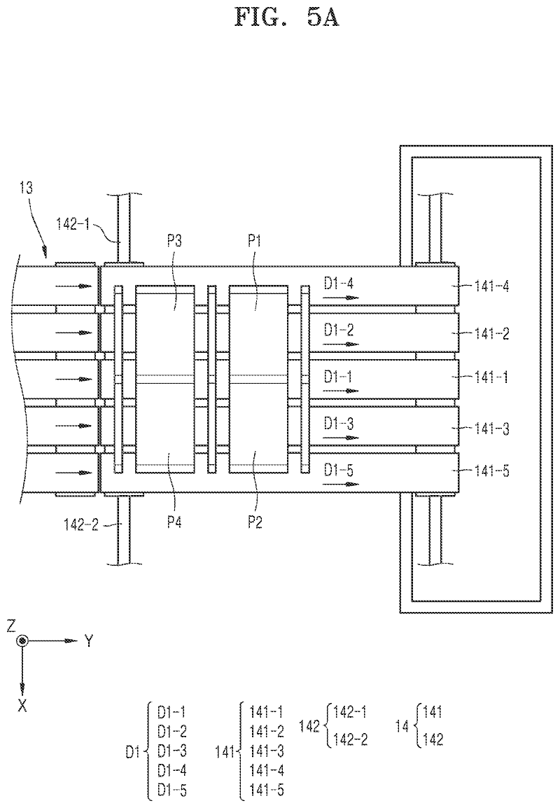

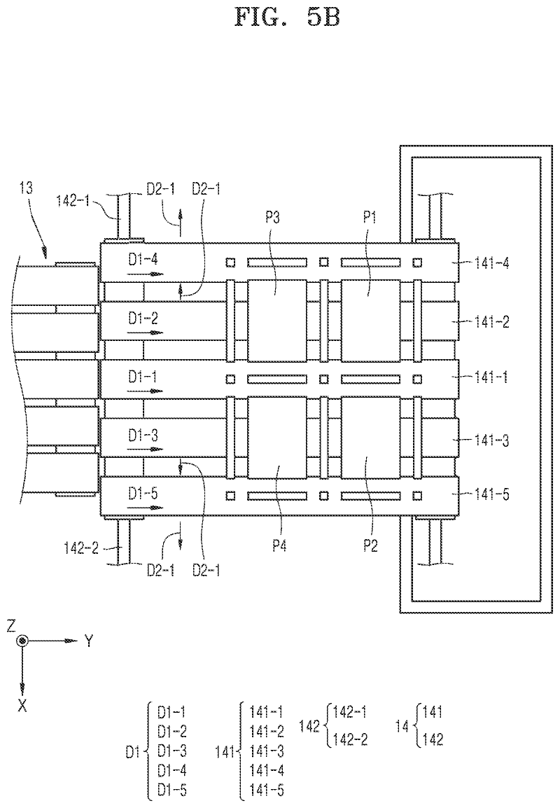

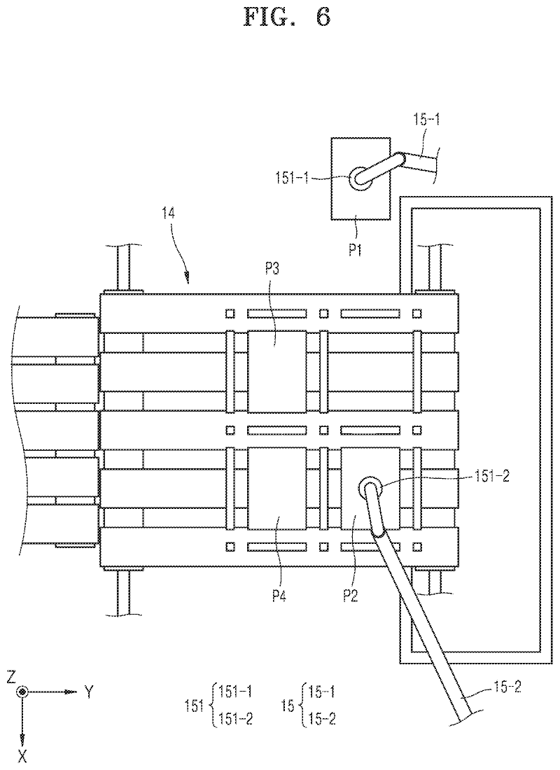

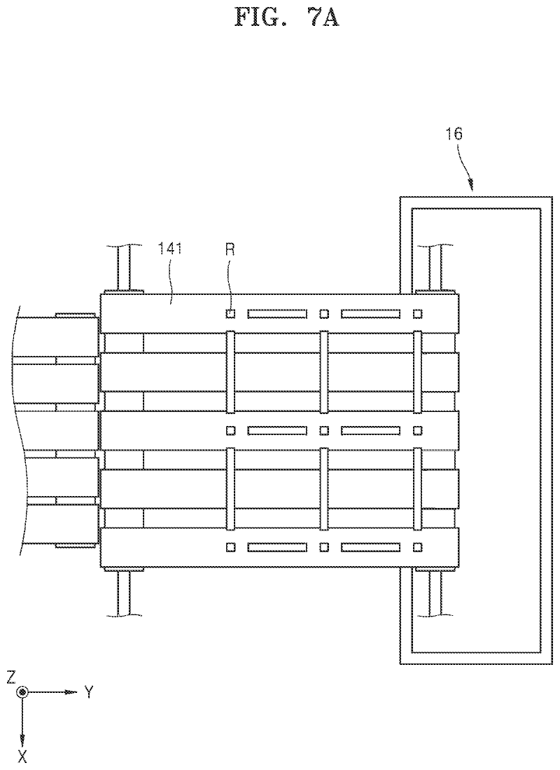

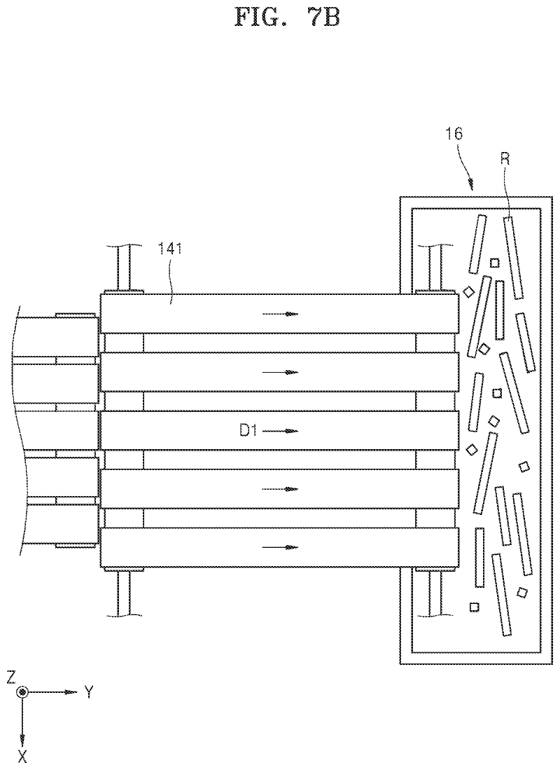

FIGS. 5A and 5B are schematic views for describing a separation unit (separation part), according to an embodiment. FIG. 6 is a schematic view for describing a transfer robot, according to an embodiment. FIGS. 7A and 7B are schematic views for describing a residue storage, according to an embodiment.

Referring to FIGS. 1 to 7B, an apparatus 1 for manufacturing a display apparatus may include a chucking unit 11, a cutting unit 12, a transfer unit 13, a separation unit 14, a transfer robot 15, and a residue storage 16.

Referring to FIGS. 1 to 2C, the chucking unit 11 may chuck a target T and may transfer the target T to the cutting unit 12. The chucking unit 11 may include a chucking unit 111 and a support unit 112 (support part).

The chucking unit 111 may chuck the target T. The chucking unit 111 may include a fixing unit 1111 (fixing part) for fixing the target T. For example, the fixing unit 1111 may include a clamp and may hold the target T by using the clamp. However, this is merely an example, and a method by which the fixing unit 1111 fixes the target T is not limited thereto.

Multiple fixing units 1111 may be provided. In this structure, the fixing units 1111 may fix the target T at multiple points. Accordingly, the fixing units 1111 may firmly fix the target T.

The chucking unit 111 may be movable in an up-down direction (e.g., a Z-axis direction) and a front-back direction (e.g., a Y-axis direction). Accordingly, as the chucking unit 111 moves while fixing the target T, the target T may be transferred to the cutting unit 12.

The support unit 112 may transfer the target T to the cutting unit 12 while supporting the target T. The support unit 112 may include a conveyor forming an endless track. In this structure, as the conveyor is driven while supporting a bottom surface (e.g., a direction facing a −Z-axis direction) of the target T, the support unit 112 may transfer the target T to the cutting unit 12.

Multiple support units 112 may be provided, and the support units 112 may be spaced apart from each other. In this structure, the fixing unit 1111 of the chucking unit 111 may be located between the support units 112. For example, as shown in FIGS. 1 to 2C, five support units 112 may be provided, and four fixing units 1111 may be provided. Accordingly, each of the four fixing units 1111 may be located between adjacent support units of the five support units 112.

Referring to FIG. 2A, the target T may be introduced to the support unit 112, and the support unit 112 may support the bottom surface (e.g., the surface facing the −Z-axis direction) of the target T. The fixing unit 1111 of the chucking unit 111 may be located above the target T. Accordingly, while the target T is introduced into the support unit 112, the fixing unit 1111 may not interfere with the introduction of the target T.

Referring to FIG. 2B, in case that the target T is introduced to the support unit 112, the chucking unit 111 may chuck the target T. The chucking unit 111 may move to chuck the target T. The chucking unit 111 may move downward (e.g., move in the −Z-axis direction) so that the fixing unit 1111 is located at the same height as a height of the target T. The chucking unit 111 may move rightward (e.g., move in a +Y-axis direction) so that the fixing unit 1111 chucks the target T. In case that the movement of the chucking unit 111 is completed, the fixing unit 1111 may fix the target T.

Referring to FIG. 2C, the chucking unit 11 may transfer the target T to the cutting unit 12. The support unit 112 may transfer the target T to the cutting unit 12 while supporting the bottom surface (e.g., the surface facing the −Z-axis direction) of the target T. The chucking unit 111 may transfer the target T to the cutting unit 12 while chucking the target T. A speed at which the support unit 112 transfers the target T and a speed at which the chucking unit 111 transfers the target T may be the same. In this structure, the target T may be transferred to the cutting unit 12 while being stably supported by the support unit 112. Also, the target T may be transferred to the cutting unit 12 delicately by the chucking unit 111.

Referring to FIGS. 1, 3A, and 3B, the cutting unit 12 may half-cut the target T. FIG. 3B is a schematic cross-sectional view taken along line III-III′ of FIG. 3A.

Half-cutting refers to making a groove in the target T so that the target T may not be completely separated. The target T that is half-cut may be completely separated through an additional separation process. Accordingly, because the target T is not separated during an operation of the cutting unit 12, the cutting unit 12 may half-cut the target T at an exact position of the target T. A process of separating the half-cut target T will be described below with reference to FIGS. 5A and 5B.

The cutting unit 12 may include a cutting frame 121 and a cutting unit 122.

The cutting frame 121 may form an outer appearance of the cutting unit 12, and may provide a space in which the cutting unit 122 is located. The cutting frame 121 may surround a space between the chucking unit 11 and the transfer unit 13.

The cutting unit 122 may be located in an inner space of the cutting frame 121 and may be connected to the cutting frame 121. The cutting unit 122 may include a cutting wheel 1221. The cutting wheel 1221 may freely rotate about a rotational axis. In a state where the cutting wheel 1221 contacts the target T, in case that a relative movement occurs between the cutting wheel 1221 and the target T, the target T may be half-cut.

The cutting unit 122 may include a first cutting unit 122-1 and a second cutting unit 122-2. The first cutting unit 122-1 may be connected to a top surface (e.g., a surface facing the −Z-axis direction) from among inner surfaces of the cutting frame 121, and the second cutting unit 122-2 may be connected to a bottom surface (e.g., a surface facing a +Z-axis direction) from among the inner surfaces of the cutting frame 121. The first cutting unit 122-1 may include a first cutting wheel 1221-1, and the second cutting unit 122-2 may include a second cutting wheel 1221-2. In this structure, the target T may contact the first cutting wheel 1221-1 and the second cutting wheel 1221-2 at the same time. For example, a top surface (e.g., a surface facing the +Z-axis direction) of the target T may contact the first cutting wheel 1221-1, and a bottom surface (e.g., a surface facing the −Z-axis direction) of the target T may contact the second cutting wheel 1221-2. Accordingly, a force applied by the first cutting unit 122-1 to the target T and a force applied by the second cutting unit 122-2 to the target T may be balanced. Accordingly, the cutting unit 122 may half-cut the target T stably and efficiently.

Referring to FIG. 3A, the target T may be half-cut in the Y-axis direction. In a state where the cutting unit 122 does not move in an X-axis direction, the chucking unit 11 may move the target T in the Y-axis direction. Accordingly, a relative movement in the Y-axis direction may occur between the target T and the cutting unit 122, and thus, the target T may be half-cut in the Y-axis direction.

Referring to FIG. 3B, the target T may be half-cut in the X-axis direction. In a state where the chucking unit 11 does not move the target T in the Y-axis direction, the cutting unit 122 may move in the X-axis direction. Accordingly, a relative movement in the X-axis direction may occur between the target T and the cutting unit 122, and thus, the target T may be half-cut in the X-axis direction.

An order of a step described with reference to FIG. 3A and a step described with reference to FIG. 3B is not limited. For example, after half-cutting of the target T in the Y-axis direction is completed as shown in FIG. 3A, half-cutting of the target T in the X-axis direction may start as shown in FIG. 3B. Also, for example, after half-cutting of the target T in the X-axis direction is completed as shown in FIG. 3B, half-cutting of the target T in the Y-axis direction may start as shown in FIG. 3A. For example, a step described with reference to FIG. 3A and a step described with reference to FIG. 3B may be simultaneously performed.

Referring to FIGS. 1 and 4, the transfer unit 13 may transfer the half-cut target T to the separation unit 14.

For example, as shown in FIG. 4, the transfer unit 13 may transfer the target T half-cut into a first portion P1, a second portion P2, a third portion P3, and a fourth portion P4 to the separation unit 14. Although the target T is half-cut into four portions in FIG. 4, this is merely an example, and the number of portions half-cut from the target T is not limited thereto.

However, for convenience of explanation, the following will be described assuming that the target T is half-cut into the first portion P1, the second portion P2, the third portion P3, and the fourth portion P4.

The transfer unit 13 may include a conveyor. In this structure, as the conveyor is driven while supporting the bottom surface (e.g., the surface facing the −Z-axis direction) of the target T, the transfer unit 13 may transfer the target T to the separation unit 14. Multiple transfer units 13 may be provided, and the transfer units 13 may be spaced apart from each other. For example, as shown in FIGS. 1 and 4, five transfer units 13 may be provided. In this structure, a position sensor for detecting a position of the target T may be located between the plurality of transfer units 13. Accordingly, the transfer unit 13 may delicately transfer the target T based on a signal detected by the position sensor.

Referring to FIGS. 1, 5A, and 5B, the separation unit 14 may separate the half-cut target T into target portions (i.e., P1, P2, P3, and P4). The separation unit 14 may include a first moving unit 141 (moving part) and a second moving unit 142.

Referring to FIG. 5A, the first moving unit 141 may be driven in a driving direction D1 to move the target T. The first moving unit 141 may include a conveyor. In this structure, as the conveyor is driven while supporting the bottom surface (e.g., the surface facing the −Z-axis direction) of the target T, the separation unit 14 may move the target T.

While the target T is moved from the transfer unit 13 to the separation unit 14, a part of the half-cut target T may be separated into the target portions P1, P2, P3, and P4. A driving speed of the transfer unit 13 and a driving speed of the first moving unit 141 may be different from each other. For example, a driving speed of the first moving unit 141 may be higher than a driving speed of the transfer unit 13. In this structure, as the half-cut target T passes through a boundary between the transfer unit 13 and the first moving unit 141, a tensile force may be applied to the half-cut target T in the Y-axis direction. Accordingly, the half-cut target T may be separated into target portions while passing through the boundary between the transfer unit 13 and the first moving unit 141, and the separated target portions may be spaced apart from each other in the Y-axis direction.

Multiple first moving units 141 may be provided. For example, the first moving unit 141 may include a 1-1^{th} moving unit 141-1 driven in a 1-1^{th} direction D1-1, a 1-2^{th} moving unit 141-2 driven in a 1-2^{th} direction D1-2, a 1-3^{th} moving unit 141-3 driven in a 1-3^{th} direction D1-3, a 1-4^{th} moving unit 141-4 driven in a 1-4^{th} direction D1-4, and a 1-5^{th} moving unit 141-5 driven in a 1-5^{th} direction D1-5. The 1-2^{th} moving unit 141-2 and the 1-3^{th} moving unit 141-3 may be located with the 1-1 moving unit 141-1 therebetween. The 1-4^{th} moving unit 141-4 may be located adjacent to the 1-2^{th} moving unit 141-2, and the 1-5^{th} moving unit 141-5 may be located adjacent to the 1-3^{th} moving unit 141-3. However, this is merely an example, and the number of first moving units 141 may vary according to their use and purpose.

Referring to FIG. 5B, the second moving unit 142 may move at least one of the first moving units 141 in a direction intersecting the driving direction D1 For example, the second moving unit 142 may move at least one of the first moving units 141 in a direction perpendicular to the driving direction D1.

The second moving unit 142 may include a 2-1^{th} moving unit 142-1 and a 2-2^{th} moving unit 142-2. The 2-1 moving unit 142-1 may move the 1-2^{th} moving unit 141-2 and the 1-4^{th} moving unit 141-4 in a 2-1^{th} direction D2-1. The 2-2^{th} moving unit 142-2 may move the 1-3^{th} moving unit 141-3 and the 1-5^{th} moving unit 141-5 in a 2-2^{th} direction D2-2. As described above, the 2-1^{th} direction D2-1 may be a direction intersecting the 1-2^{th} direction D1-2 and the 1-4^{th} direction D1-4, and the 2-2^{th} direction D2-2 may be a direction intersecting the 1-3^{th} direction D1-3 and the 1-5^{th} direction D1-5.

For example, the 1-1^{th} moving unit 141-1 may be driven in the 1-1^{th} direction D1-1, the 1-2^{th} moving unit 141-2 may be driven in the 1-2^{th} direction D1-2 and may move in the 2-1^{th} direction D2-1, the 1-3^{th} moving unit 141-3 may be driven in the 1-3^{th} direction D1-3 and may move in the 2-2^{th} direction D2-2, the 1-4^{th} moving unit 141-4 may be driven in the 1-4^{th} direction D1-4 and may move in the 2-1^{th} direction D2-1, and the 1-5^{th} moving unit 141-5 may be driven in the 1-5^{th} direction D1-5 and may move in the 2-2^{th} direction D2-2.

In this structure, as the second moving unit 142 moves the first moving unit 141, a distance between the first moving units 141 may gradually increase. Accordingly, while the half-cut target T moves on the first moving unit 141, a tensile force may be applied to the half-cut target T in the X-axis direction. Accordingly, the half-cut target T may be entirely separated while moving on the first moving unit 141, and the separated target portions P1, P2, P3, and P4 may be spaced apart from each other in the X-axis direction. For example, as each of the first moving units 141 is driven, a distance between the separated target portions P1, P2, P3, and P4 may gradually increase.

Referring to FIGS. 1 and 6, the transfer robot 15 may transfer the separated target portions P1, P2, P3, and P4 from the separation unit 14 to a storage location.

The transfer robot 15 may include an adsorbing unit 151 (adsorbing part) for adsorbing the separated target portions P1, P2, P3, and P4. In this structure, the transfer robot 15 may lift and transfer the target portions P1, P2, P3, and P4 to the storage location by adsorbing top surfaces (e.g., surfaces facing the +Z-axis direction) of the target portions P1, P2, P3, and P4. Accordingly, while the transfer robot 15 transfers the target portions P1, P2, P3, and P4, damage to the target portions P1, P2, P3, and P4 may be reduced.

The transfer robot 15 may sequentially transfer the target portions P1, P2, P3, and P4 from the separation unit 14 to the storage location. For example, the transfer robot 15 may sequentially transfer the first portion P1, the second portion P2, the third portion P3, and the fourth portion P4 to the storage location. Accordingly, damage to the target portions P1, P2, P3, and P4, which may occur in case that the target portions P1, P2, P3, and P4 are simultaneously transferred, may be reduced.

The transfer robot 15 may include a first transfer robot 15-1 and a second transfer robot 15-2. The first transfer robot 15-1 may include a first adsorbing unit 151-1, and the second transfer robot 15-2 may include a second adsorbing unit 151-2. While the first transfer robot 15-1 transfers the first portion P1 to the storage location, the second transfer robot 15-2 may adsorb the second portion P2. While the second transfer robot 15-2 transfers the second portion P2 to the storage location, the first transfer robot 15-1 may adsorb the third portion P3. While the first transfer robot 15-1 transfers the third portion P3 to the storage location, the second transfer robot 15-2 may adsorb the fourth portion P4. In this structure, the separated target portions P1, P2, P3, and P4 may be rapidly transferred to the storage location.

Referring to FIGS. 1, 7A, and 7B, the residue storage 16 may store residue R separated from the separation unit 14.

Referring to FIG. 7A, in case that the target portions P1, P2, P3, and P4 are transferred to the storage location by the transfer robot 15, the residue R may remain on the first moving unit 141.

Referring to FIG. 7B, while the residue R remains on the first moving unit 141, the first moving unit 141 may be driven in the driving direction D1. In this structure, the residue R on the first moving unit 141 may also move in the driving direction D1 of the first moving unit 141. The residue storage 16 may be located below an end of the first moving unit 141. For example, when viewed from above as shown in FIGS. 5A and 5B, the end of the first moving unit 141 and the residue storage 16 may overlap each other. Accordingly, as the first moving unit 141 is continuously driven, the residue R on the first moving unit 141 may fall to the residue storage 16. The residue storage 16 may crush the stored residue R of the target portions P1, P2, P3, and P4.

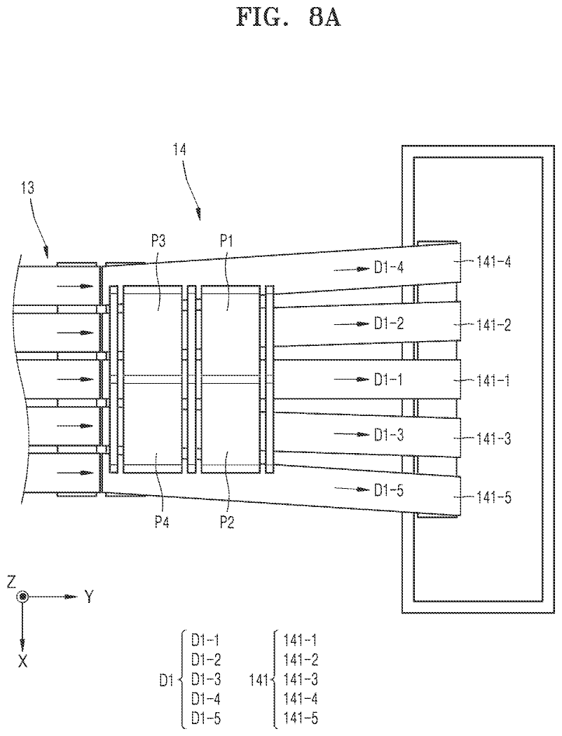

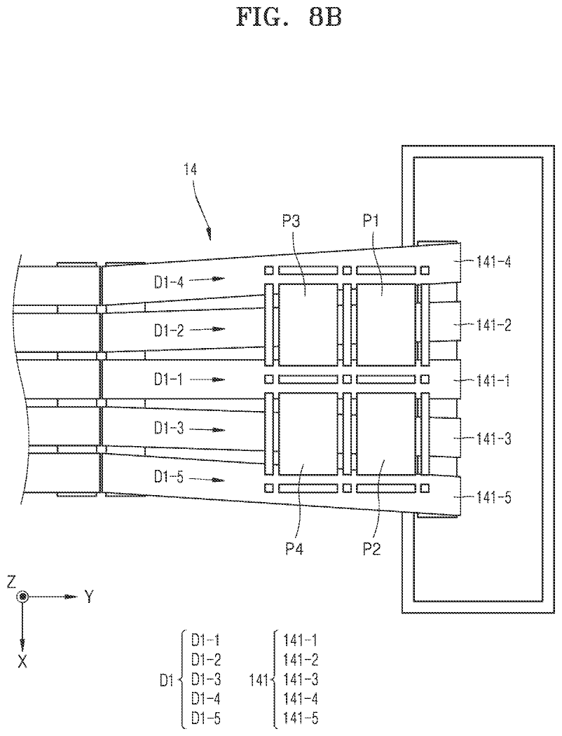

FIGS. 8A and 8B are schematic views for describing a separation unit, according to another embodiment.

In FIGS. 8A and 8B, redundant description to that provided above with reference to FIGS. 5A and 5B will be omitted for convenience of explanation.

The driving directions D1 of at least two of the first moving units 141 may intersect each other. For example, the first moving units 141 may be arranged so that the 1-1^{th} direction D1-1, the 1-2^{th} direction D1-2, the 1-3^{th} direction D1-3, the 1-4^{th} direction D1-4, and the 1-5^{th} direction D1-5 intersect each other. In this structure, a distance between the 1-1^{th} moving unit 141-1, the 1-2^{th} moving unit 141-2, the 1-3^{th} moving unit 141-3, the 1-4^{th} moving unit 141-4, and the 1-5^{th} moving unit 141-5 may gradually increase, in the driving direction D1 of the first moving unit 141.

In this structure, while the half-cut target T moves on the first moving unit 141, a tensile force may be applied to the half-cut target T in the X-axis direction. Accordingly, the half-cut target T may be entirely separated while moving on the first moving unit 141, and the separated target portions P1, P2, P3, and P4 may be spaced apart from each other in the X-axis direction.

For example, as each of the first moving units 141 is driven, a distance between the separated target portions P1, P2, P3, and P4 may gradually increase.

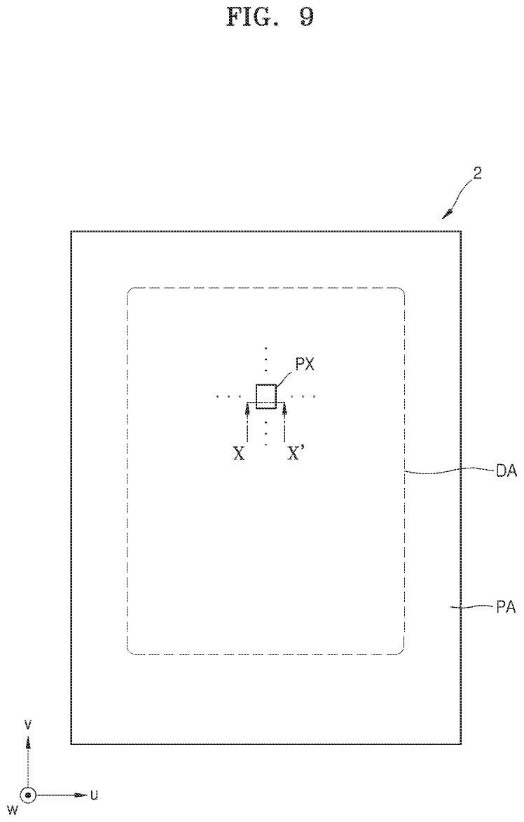

FIG. 9 is a schematic plan view illustrating a display apparatus, according to an embodiment;

Referring to FIG. 9, a display apparatus 2 may include a display area DA and a peripheral area PA located outside the display area DA. The display apparatus 2 may provide an image through an array of pixels PX that are two-dimensionally arranged in the display area DA.

The peripheral area PA where an image may not be provided may entirely or partially surround the display area DA. A driver or the like for providing an electrical signal or power to a pixel circuit corresponding to each of the pixels PX may be located in the peripheral area PA. A pad to which an electronic device, a printed circuit board, or the like may be electrically connected may be located in the peripheral area PA.

Although the display apparatus 2 may include an organic light-emitting diode (OLED) as a light-emitting element, the display apparatus 2 of the disclosure is not limited thereto. In another embodiment, the display apparatus 2 may be a light-emitting display apparatus including an inorganic light-emitting diode, that is, an inorganic light-emitting display apparatus. The inorganic light-emitting diode may include a PN diode including inorganic semiconductor-based materials. In case that a voltage is applied to a PN junction diode in a forward direction, holes and electrons may be injected, and energy generated by recombination of the holes and electrons may be converted into light energy to emit light of a certain color. The inorganic light-emitting diode may have a width of several to hundreds of micrometers, and in some embodiments, the inorganic light-emitting diode may be referred to as a micro-LED. In another embodiment, the display apparatus 2 may be a quantum dot light-emitting display apparatus.

The display apparatus 2 may be used as a display screen of not only a portable electronic device such as a mobile phone, a smartphone, a tablet personal computer (PC), a mobile communication terminal, an electronic organizer, an electronic book, a portable multimedia player (PMP), a navigation device, or an ultra-mobile PC (UMPC) but also any of various products such as a television, a laptop computer, a monitor, an advertisement board, or an Internet of things (IoT) device. The display apparatus 2 according to an embodiment may be used in a wearable device such as a smart watch, a watch phone, a glasses-type display, or a head-mounted display (HMD). Also, the display apparatus 2 according to an embodiment may be applied to a center information display (CID) located on an instrument panel, a center fascia, or a dashboard of a vehicle, a room mirror display replacing a side-view mirror of a vehicle, or a display screen located on the back of a front seat for entertainment for a back seat of a vehicle.

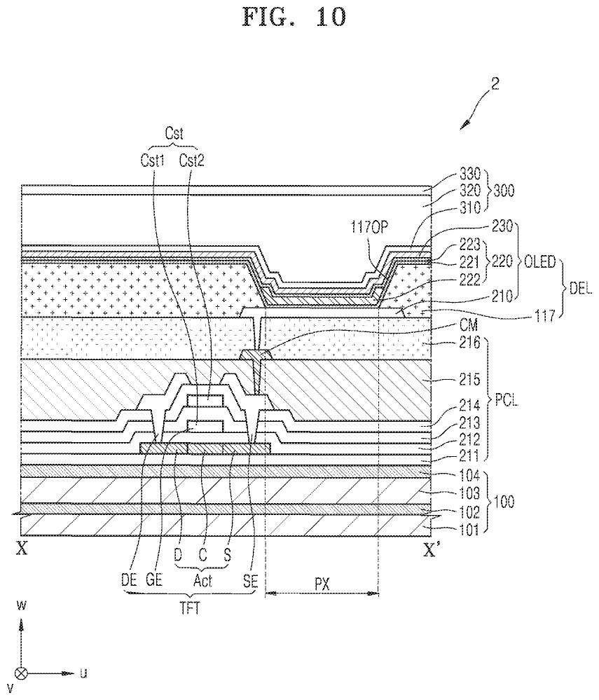

FIG. 10 is a schematic cross-sectional view illustrating a display apparatus, taken along line X-X′ of FIG. 9, according to an embodiment.

Referring to FIG. 10, the display apparatus 2 may have a structure in which a substrate 100, a pixel circuit layer PCL, a display element layer DEL, and an encapsulation layer 300 are stacked.

The substrate 100 may have a multi-layer structure including a base layer including a polymer resin and an inorganic layer. For example, the substrate 100 may include a base layer including a polymer resin and a barrier layer of an inorganic insulating layer. For example, the substrate 100 may include a first base layer 101, a first barrier layer 102, a second base layer 103, and a second barrier layer 104, which are sequentially stacked. Each of the first base layer 101 and the second base layer 103 may include polyimide (PI), polyethersulfone (PES), polyarylate, polyetherimide (PEI), polyethylene naphthalate (PEN), polyethylene terephthalate (PET), polyphenylene sulfide (PPS), polycarbonate, cellulose triacetate (TAC), and/or cellulose acetate propionate (CAP). Each of the first barrier layer 102 and the second barrier layer 104 may include an inorganic insulating material such as silicon oxide, silicon oxynitride, and/or silicon nitride. The substrate 100 may be flexible.

The pixel circuit layer PCL may be located on the substrate 100. In FIG. 12, the pixel circuit layer PCL includes a thin-film transistor TFT, and a buffer layer 211, a first gate insulating layer 212, a second gate insulating layer 213, an interlayer insulating layer 214, a first planarization insulating layer 215, and a second planarization insulating layer 216 located under and/or over elements of the thin-film transistor TFT.

The buffer layer 211 may reduce or block penetration of a foreign material, moisture, or external air from the bottom of the substrate 100, and may planarize the substrate 100. The buffer layer 211 may include an inorganic insulating material such as silicon oxide, silicon oxynitride, or silicon nitride, and may have a single or multi-layer structure including the above material.

The thin-film transistor TFT on the buffer layer 211 may include a semiconductor layer Act, and the semiconductor layer Act may include polysilicon. For example, the semiconductor layer Act may include an amorphous silicon, an oxide semiconductor, or an organic semiconductor. The semiconductor layer Act may include a channel region C, and a drain region D and a source region S located on both sides of the channel region C. A gate electrode GE may overlap the channel region C.

The gate electrode GE may include a low-resistance metal material. The gate electrode GE may include a conductive material including molybdenum (Mo), aluminum (Al), copper (Cu), or titanium (Ti), and may have a single or multi-layer structure including the above material.

The first gate insulating layer 212 between the semiconductor layer Act and the gate electrode GE may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The zinc oxide (ZnOₓ) may be zinc oxide (ZnO) and/or zinc peroxide (ZnO₂).

The second gate insulating layer 213 may cover the gate electrode GE. The second gate insulating layer 213 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ), like the first gate insulating layer 212. The zinc oxide (ZnOₓ) may be zinc oxide (ZnO) and/or zinc peroxide (ZnO₂).

An upper electrode Cst2 of a storage capacitor Cst may be located on the second gate insulating layer 213. The upper electrode Cst2 may overlap the first gate electrode GE that is located below the upper electrode Cst2. The gate electrode GE and the upper electrode Cst2 overlapping each other with the second gate insulating layer 213 therebetween may constitute the storage capacitor Cst. For example, the gate electrode GE may function as the lower electrode Cst1 of the storage capacitor Cst.

As such, the storage capacitor Cst and the thin-film transistor TFT may overlap each other. In some embodiments, the storage capacitor Cst may not overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single or multi-layer structure including the above material.

The interlayer insulating layer 214 may cover the upper electrode Cst2. The interlayer insulating layer 214 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The zinc oxide (ZnOₓ) may be zinc oxide (ZnO) and/or zinc peroxide (ZnO₂). The interlayer insulating layer 214 may have a single or multi-layer structure including the above inorganic insulating material.

Each of a drain electrode DE and a source electrode SE may be located on the interlayer insulating layer 214. The drain electrode DE and the source electrode SE may be respectively connected to the drain region D and the source region S through contact holes formed in insulating layers under the drain electrode DE and the source electrode SE. Each of the drain electrode DE and the source electrode SE may include a material having excellent conductivity.

Each of the drain electrode DE and the source electrode SE may include a conductive material including molybdenum (Mo), aluminum (Al), copper (Cu), or titanium (Ti), and may have a single or multi-layer structure including the above material. In an embodiment, each of the drain electrode DE and the source electrode SE may have a multi-layer structure including Ti/Al/Ti.

The first planarization insulating layer 215 may cover the drain electrode DE and the source electrode SE. The first planarization insulating layer 215 may include an organic insulating material such as a general-purpose polymer (e.g., polymethyl methacrylate (PMMA) or polystyrene (PS)), a polymer derivative having a phenol-based group, an acrylic polymer, an imide-based polymer, an arylene ether-based polymer, an amide-based polymer, a fluorinated polymer, a p-xylene-based polymer, a vinyl alcohol-based polymer, or a blend thereof.

The second planarization insulating layer 216 may be located on the first planarization insulating layer 215. The second planarization insulating layer 216 may include the same material as that of the first planarization insulating layer 215, and may include an organic insulating material such as a general-purpose polymer (e.g., polymethyl methacrylate (PMMA) or polystyrene (PS)), a polymer derivative having a phenol-based group, an acrylic polymer, an imide-based polymer, an arylene ether-based polymer, an amide-based polymer, a fluorinated polymer, a p-xylene-based polymer, a vinyl alcohol-based polymer, or a blend thereof.

The display element layer DEL may be located on the pixel circuit layer PCL having the above structure. The display element layer DEL may include an organic light-emitting diode OLED as a display element (i.e., a light-emitting element), and the organic light-emitting diode OLED may have a structure in which a pixel electrode 210, an intermediate layer 220, and a common electrode 230 are stacked. The organic light-emitting diode OLED may emit, for example, red light, green light, or blue light, or the organic light-emitting diode OLED may emit, for another example, red light, green light, blue light, or white light. The organic light-emitting diode OLED may emit light through an emission area, and the emission area may be defined as the pixel PX.

The pixel electrode 210 of the organic light-emitting diode OLED may be electrically connected to the thin-film transistor TFT through contact holes formed in the second planarization insulating layer 216 and the first planarization insulating layer 215 and a contact metal CM located on the first planarization insulating layer 215.

The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the pixel electrode 210 may further include a film formed of ITO, IZO, ZnO, or In₂O₃ over/under the reflective film.

A pixel-defining film 117 having an opening 1170P through which a central portion of the pixel electrode 210 may be exposed is located on the pixel electrode 210. The pixel-defining film 117 may include an organic insulating material and/or an inorganic insulating material. The opening 1170P may define the emission area of light emitted by the organic light-emitting diode OLED. For example, a size/width of the opening 1170P may correspond to a size/width of the emission area. Accordingly, a size and/or a width of the pixel PX may depend on a size and/or a width of the opening 1170P of the pixel-defining film 117.

The intermediate layer 220 may include an emission layer 222 formed to correspond to the pixel electrode 210. Each emission layer 222 may include a high molecular weight organic material or a low molecular weight organic material that emits light of a certain color. For example, the emission layer 222 may include an inorganic light-emitting material or may include quantum dots.

In an embodiment, the intermediate layer 220 may include a first functional layer 221 and a second functional layer 223 respectively located under and over the emission layer 222. The first functional layer 221 may include, for example, a hole transport layer (HTL), or may include an HTL and a hole injection layer (HIL). The second functional layer 223 that is an element located on the emission layer 222 may include an electron transport layer (ETL) and/or an electron injection layer (EIL). The first functional layer 221 and/or the second functional layer 223 may be a common layer entirely covering the substrate 100, like the common electrode 230 described below.

The common electrode 230 may be located on the pixel electrode 210, and may overlap the pixel electrode 210. The common electrode 230 may be formed of a conductive material having a low work function. For example, the common electrode 230 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. For example, the common electrode 230 may further include a layer formed of ITO, IZO, ZnO, or In₂O₃ on the (semi)transparent layer including the above material. The common electrode 230 may be integrally formed to entirely cover the substrate 100.

The encapsulation layer 300 may be located on the display element layer DEL and may cover the display element layer DEL. The encapsulation layer 300 may include at least one inorganic encapsulation layer and at least one organic encapsulation layer. In an embodiment, as shown in FIG. 10, the encapsulation layer 300 includes a first inorganic encapsulation layer 310, an organic encapsulation layer 320, and a second inorganic encapsulation layer 330, which are sequentially stacked.

Each of the first inorganic encapsulation layer 310 and the second inorganic encapsulation layer 330 may include at least one inorganic material from among aluminum oxide, titanium oxide, tantalum oxide, hafnium oxide, zinc oxide, silicon oxide, silicon nitride, and silicon oxynitride. The organic encapsulation layer 320 may include a polymer-based material. Examples of the polymer-based material may include an acrylic resin, an epoxy resin, polyimide, and polyethylene. In an embodiment, the organic encapsulation layer 320 may include acrylate. The organic encapsulation layer 320 may be formed by curing a monomer or applying a polymer. The organic encapsulation layer 320 may be transparent.

Although not shown, a touch sensor layer may be located on the encapsulation layer 300, and an optical functional layer may be located on the touch sensor layer. The touch sensor layer may obtain coordinate information according to an external input, for example, a touch event. The optical functional layer may reduce a reflectance of light (external light) incident on a display apparatus, and/or improve color purity of light emitted from the display apparatus. In an embodiment, the optical functional layer may include a phase retarder and/or a polarizer. The phase retarder may be a film-type phase retarder or a liquid crystal coating-type phase retarder, and may include a λ/2 phase retarder and/or a V/4 phase retarder. The polarizer may also be a film-type polarizer or a liquid crystal coating-type polarizer. The film-type polarizer may include a stretchable synthetic resin film, and the liquid crystal coating-type polarizer may include liquid crystals arranged in a certain arrangement. The phase retarder and the polarizer may further include a protective film.

An adhesive member may be located between the touch electrode layer and the optical functional layer. The adhesive member may be a general member without limitation. The adhesive member may be a pressure sensitive adhesive (PSA).

The target T described with reference to FIGS. 1 to 8B may include at least one of the substrate 100, the pixel circuit layer PCL, the display element layer DEL, and the encapsulation layer 300 described with reference to FIG. 10.

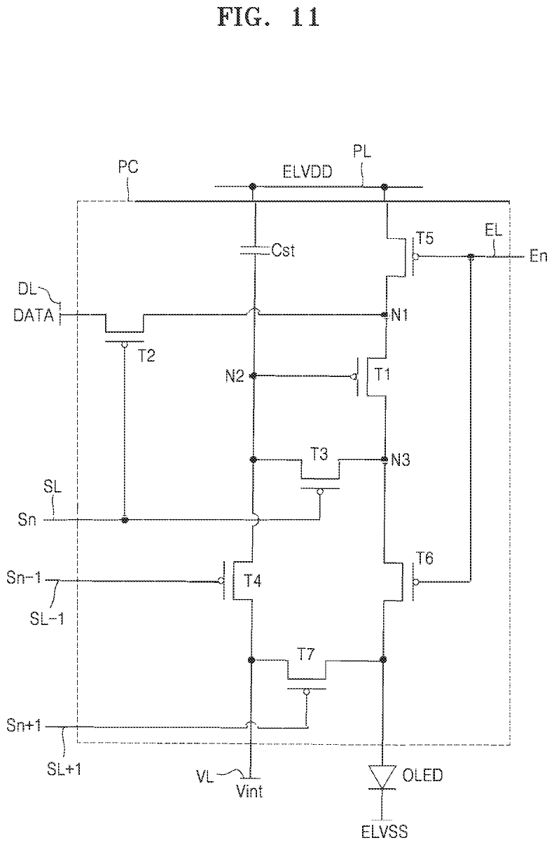

FIG. 11 is a schematic diagram of an equivalent circuit illustrating a pixel, according to an embodiment.

Referring to FIG. 11, a pixel circuit PC may include first to seventh transistors T1 to T7, and according to a type (p-type or n-type) of a transistor and/or an operation condition, a first terminal of each of the first to seventh transistors T1 to T7 may be a source terminal or a drain terminal and a second terminal may be a terminal different from the first terminal. For example, in case that the first terminal is a source terminal, the second terminal may be a drain terminal.

The pixel circuit PC may be connected to a first scan line SL that transmits a first scan signal Sn, a second scan line SL−1 that transmits a second scan signal Sn−1, a third scan line SL+1 that transmits a third scan signal Sn+1, an emission control line EL that transmits an emission control signal En, a data line DL that transmits a data signal DATA, a driving voltage line PL that transmits a driving voltage ELVDD, and an initialization voltage line VL that transmits an initialization voltage Vint.

The first transistor T1 may include a gate terminal connected to a second node N2, a first terminal connected to a first node N1, and a second terminal connected to a third node N3.

The first transistor T1 functions as a driving transistor, and receives the data signal DATA and supplies driving current to a light-emitting element according to a switching operation of the second transistor T2. The light-emitting element may be an organic light-emitting element OLED.

The second transistor T2 (switching transistor) may include a gate terminal connected to the first scan line SL, a first terminal connected to the data line DL, and a second terminal connected to the first node N1 (or the first terminal of the first transistor T1). The second transistor T2 may be turned on according to the first scan signal Sn received through the first scan line SL, and may perform a switching operation of transmitting the data signal DATA received through the data line DL to the first node N1.

The third transistor T3 (compensation transistor) may include a gate terminal connected to the first scan line SL, a first terminal connected to the second node N2 (or the gate terminal of the first transistor T1), and a second terminal connected to the third node N3 (or the second terminal of the first transistor T1). The third transistor T3 may be turned on according to the first scan signal Sn received through the first scan line SL, and may diode-connect the first transistor T1. The third transistor T3 may have a structure in which two or more transistors are connected in series.

The fourth transistor T4 (first initialization transistor) may include a gate terminal connected to the second scan line SL−1, a first terminal connected to the initialization voltage line VL, and a second terminal connected to the second node N2. The fourth transistor T4 may be turned on according to the second scan signal Sn−1 received through the second scan line SL−1, and may initialize a gate voltage of the first transistor T1 by transmitting the initialization voltage Vint to the gate terminal of the first transistor T1. The fourth transistor T4 may have a structure in which two or more transistors are connected in series.

The fifth transistor T5 (first emission control transistor) may include a gate terminal connected to the emission control line EL, a first terminal connected to the driving voltage line PL, and a second terminal connected to the first node N1. The sixth transistor T6 (second emission control transistor) includes a gate terminal connected to the emission control line EL, a first terminal connected to the third node N3, and a second terminal connected to a pixel electrode of the organic light-emitting element OLED. The fifth transistor T5 and the sixth transistor T6 may be simultaneously turned on according to the emission control signal En received through the emission control line EL, and driving current flows through the organic light-emitting element OLED.

The seventh transistor T7 (second initialization transistor) may include a gate terminal connected to the third scan line SL+1, a first terminal connected to the second terminal of the sixth transistor T6 and the pixel electrode of the organic light-emitting element OLED, and a second terminal connected to the initialization voltage line VL. The seventh transistor T7 may be turned on according to the third scan signal Sn+1 received through the third scan line SL+1, and may initialize a voltage of the pixel electrode of the organic light-emitting element OLED by transmitting the initialization voltage Vint to the pixel electrode of the organic light-emitting element OLED. The seventh transistor T7 may be omitted.

A capacitor Cst may include a first electrode connected to the second node N2 and a second electrode connected to the driving voltage line PL.

The organic light-emitting element OLED may include the pixel electrode and a counter electrode facing the pixel electrode, and the counter electrode may receive a common voltage ELVSS. The organic light-emitting element OLED may receive driving current from the first transistor T1 to emit light of a certain color, thereby displaying an image. The counter electrode may be commonly, that is, integrally, provided over a plurality of pixels.

According to embodiments, because a half-cut target is completely separated by using a simple structure, defects of the target may be reduced.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. An apparatus for manufacturing a display apparatus, the apparatus comprising:
a separation part that separates a half-cut target into a plurality of target portions, wherein
the separation part comprises a plurality of first moving parts each driven in a driving direction to move the plurality of target portions, and
as each of the plurality of first moving parts is driven, a distance between the plurality of target portions separated gradually increases.

2. The apparatus of claim 1, wherein at least one of the plurality of first moving parts comprises a conveyor forming an endless track.

3. The apparatus of claim 1, further comprising:
a second moving part that moves at least one of the plurality of first moving parts in a direction intersecting the driving direction.

4. The apparatus of claim 3, wherein the second moving part moves at least one of the plurality of first moving parts in a direction perpendicular to the driving direction.

5. The apparatus of claim 1, wherein driving directions of at least two of the plurality of first moving parts intersect each other.

6. The apparatus of claim 1, further comprising:
a transfer robot that transfers the plurality of target portions to a storage location.

7. The apparatus of claim 6, wherein
the transfer robot comprises:
a first transfer robot; and
a second transfer robot, and
the first transfer robot and the second transfer robot sequentially transfer the plurality of target portions to the storage location.

8. The apparatus of claim 6, wherein the transfer robot comprises an adsorbing part that adsorbs the plurality of target portions.

9. The apparatus of claim 1, further comprising:
a residue storage storing residue of the plurality of target portions separated by the separation part.

10. The apparatus of claim 9, wherein the residue storage crushes the stored residue of the plurality of target portions.

11. A method of manufacturing a display apparatus, the method comprising:
half-cutting a target; and
separating the half-cut target into a plurality of target portions, wherein
the separating comprises:
driving a 1-1^{th} moving part in a 1-1^{th} direction to move at least one of the plurality of target portions; and
driving a 1-2^{th} moving part in a 1-2^{th} direction to move the at least one of the plurality of target portions, and
in case that each of the 1-1 moving part and the 1-2^{th} moving part is driven, a distance between the plurality of target portions separated gradually increases.

12. The method of claim 11, wherein at least one of the 1-1 moving part and the 1-2^{th} moving part comprises a conveyor forming an endless track.

13. The method of claim 11, wherein the separating further comprises driving a 2-1^{th} moving part to move the 1-2^{th} moving part in a 2-1^{th} direction intersecting the 1-1^{th} direction.

14. The method of claim 13, wherein the driving of the 2-1^{th} moving part to move the 1-2^{th} moving part in the 2-1^{th} direction comprises driving the 2-1^{th} moving part to move the 1-2^{th} moving part in the 2-1^{th} direction perpendicular to the 1-1^{th} direction.

15. The method of claim 11, wherein the 1-1^{th} direction and the 1-2^{th} direction intersect each other.

16. The method of claim 11, further comprising:
transferring the plurality of target portions to a storage location by using a transfer robot.

17. The method of claim 16, wherein the transferring of the plurality of target portions comprises sequentially transferring the plurality of target portions to the storage location by using a first transfer robot and a second transfer robot.

18. The method of claim 16, wherein the transfer robot comprises an adsorbing part that adsorbs the plurality of target portions.

19. The method of claim 11, further comprising:
storing residue of the plurality of target portions separated in a residue storage.

20. The method of claim 19, wherein the residue storage crushes the stored residue of the plurality of target portions.
